(19) United States
(12) Patent Application Publication
(10) Pub. No.: US 2025/0199031 A1
(43) Pub. Date: Jun. 19, 2025

(54) PROBE, PROBE-HOLDING DEVICE, AND METHOD FOR MANUFACTURING PROBE

(71) Applicant: Kabushiki Kaisha Nihon Micronics, Tokyo (JP)

(72) Inventor: Yasutaka KISHI, Aomori (JP)

(21) Appl. No.: 18/848,855

(22) PCT Filed: Feb. 21, 2023
(86) PCT No.: PCT/JP2023/006204

§ 371 Date: Sep. 19, 2024

(30) Foreign Application Priority Data
Mar. 23, 2022 (JP) 2022-047137

(51) Int. Cl. G01R 1/067; G01R 3/00

(52) U.S. Cl. CPC G01R 1/06727; G01R 1/06705; G01R 3/00

(57) ABSTRACT

A probe includes a tip portion, an arm portion, a support portion, and a guide portion. The tip portion includes a contact portion that comes into contact with an object to be inspected. The arm portion has a cantilever structure including a connecting arm that links a free end and a fixed end, and the free end is connected to the tip portion. The support portion is connected to the fixed end. The guide portion is connected to an installation area of the arm portion oriented in a tip direction where the object to be inspected is located as viewed from the contact portion, and protrudes in the tip direction from the installation area.

### TECHNICAL FIELD

The disclosure relates to a probe used for inspecting an object to be inspected, a probe holding device, and a method for manufacturing a probe.

### BACKGROUND ART

A probe having a cantilever structure is used for inspecting an object to be inspected. A probe having a cantilever structure has an arm portion that links: a free end to which a tip portion to be brought in contact with an object to be inspected is connected; and a fixed end to which the probe is fixed. For example, a probe is used for inspection with the fixed end connected to a probe substrate.

### CITATION LIST

### Patent Literature

Patent Literature 1: JP 2007-303834 A

### SUMMARY OF THE INVENTION

### Problem to Be Solved by the Invention

A probe is mounted on a probe substrate while the position of a tip portion of the probe is recognized. Thus, even when an arm portion of the probe is distorted, the distortion of the probe cannot be detected when it is mounted on the probe substrate. When the probe is mounted on the probe substrate in a distorted state, the tip portion of the probe cannot be brought into precise contact with the center of an electrode pad of an object to be inspected during inspection. When the tip portion of the probe is brought into contact with the object to be inspected while deviating from the center of the electrode pad, contact strength between the probe and the object to be inspected decreases, and electrical resistance between the probe and the electrode pad of the object to be inspected increases. Consequently, an issue, such as a decrease in the accuracy of the inspection, occurs.

An object of the present invention is to provide a probe that has a cantilever structure and is capable of detecting distortion of the probe, a probe holding device, and a method for manufacturing a probe.

### Means for Solving the Problem

A probe according to one aspect of the present invention includes a tip portion, an arm portion, a support portion, and a guide portion. The tip portion includes a contact portion that comes into contact with an object to be inspected. The arm portion has a cantilever structure including a connecting arm that links a free end and a fixed end, and the free end is connected to the tip portion. The support portion is connected to the fixed end. The guide portion is connected to an installation area of the arm portion oriented in a tip direction where the object to be inspected is located as viewed from the contact portion, and protrudes in the tip direction from the installation area.

### Effect of the Invention

The present invention provides a probe that has a cantilever structure and is capable of detecting distortion of the probe, a probe holding device, and a method for manufacturing a probe.

### BRIEF DESCRIPTION OF THE DRAWINGS

FIG. 1 is a schematic diagram illustrating a configuration of a probe according to an embodiment.

FIG. 2 is a schematic diagram illustrating a configuration of a probe of a comparative example.

FIG. 3 is a schematic diagram for describing a method for inspecting the probe according to the embodiment.

FIG. 4 is a schematic diagram for describing the position of a guide portion of the probe according to the embodiment.

FIG. 5A is a schematic plan view for describing a method for manufacturing the probe according to the embodiment (part 1).

FIG. 5B is a schematic side view for describing the method for manufacturing the probe according to the embodiment (part 1).

FIG. 6A is a schematic plan view for describing the method for manufacturing the probe according to the embodiment (part 2).

FIG. 6B is a schematic side view for describing the method for manufacturing the probe according to the embodiment (part 2).

FIG. 7A is a schematic plan view for describing the method for manufacturing the probe according to the embodiment (part 3).

FIG. 7B is a schematic side view for describing the method for manufacturing the probe according to the embodiment (part 3).

FIG. 8A is a schematic plan view for describing the method for manufacturing the probe according to the embodiment (part 4).

FIG. 8B is a schematic side view for describing the method for manufacturing the probe according to the embodiment (part 4).

FIG. 9 is a schematic diagram illustrating a configuration of a probe holding device according to the embodiment.

FIG. 10A is a schematic plan view illustrating a configuration of a first guide plate of the probe holding device according to the embodiment.

FIG. 10B is a schematic plan view illustrating a configuration of a second guide plate of the probe holding device according to the embodiment.

FIG. 11A is a schematic diagram illustrating an example of the shape of the guide portion of the probe according to the embodiment.

FIG. 11B is a schematic diagram illustrating another example of the shape of the guide portion of the probe according to the embodiment.

FIG. 12A is a schematic diagram illustrating an example of the position of the guide portion of the probe according to the embodiment.

FIG. 12B is a schematic diagram illustrating another example of the position of the guide portion of the probe according to the embodiment.

FIG. 12C is a schematic diagram illustrating yet another example of the position of the guide portion of the probe according to the embodiment.

FIG. 12D is a schematic diagram illustrating yet another example of the position of the guide portion of the probe according to the embodiment.

FIG. 13 is a schematic diagram illustrating a configuration of a probe according to another embodiment.

### DETAILED DESCRIPTION OF THE INVENTION

Embodiments of the present invention will now be described with reference to the drawings. In the description of the following drawings, the same or similar portions are denoted by the same or similar reference numerals. However, it should be noted that the drawings are schematic, and thickness proportions and the like of the portions differ from actual values. Furthermore, the drawings include portions where a relationship and a proportion of dimensions differ therebetween. The following embodiments illustrate a device and a method for embodying the technical concept of the present invention, and the embodiments of the present invention do not limit the material, shape, structure, arrangement, and the like of the components as follows.

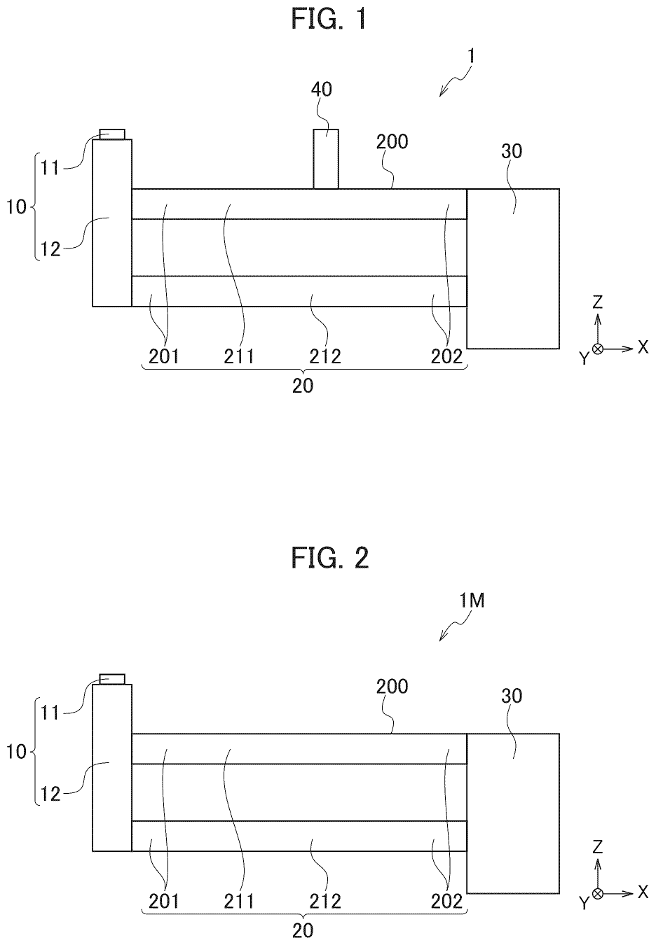

A probe 1 according to an embodiment of the present invention illustrated in FIG. 1 is used for inspection of an object to be inspected. The probe 1 includes a tip portion 10, an arm portion 20 having a cantilever structure, a support portion 30, and a guide portion 40. The tip portion 10 includes a contact portion 11 that comes into contact with an object to be inspected, and a linkage portion 12 that is linked to the contact portion 11. The tip portion 10 is connected to a free end 201 of the arm portion 20 at the linkage portion 12. The support portion 30 is connected to a fixed end 202 of the arm portion 20. The support portion 30 is fixed to a probe substrate on which the probe 1 is mounted, for example. The guide portion 40 is connected to the arm portion 20.

Inspection of an object to be inspected using the probe 1 is performed with the contact portion 11 of the tip portion 10 being in contact with the object to be inspected. The tip portion 10 is connected to the arm portion 20 in such a manner that the tip of the contact portion 11 comes in contact with the object to be inspected. The support portion 30 is electrically connected to an inspection device (not illustrated), such as a tester, through a probe substrate, for example. That is, an electrical signal propagates between the inspection device and the object to be inspected through the probe 1. Thus, a highly conductive material, such as a metal, may be used in the probe 1, which propagates the electrical signal.

The arm portion 20 has multiple connecting arms, each of which links the free end 201 and the fixed end 202. The arm portion 20 illustrated in FIG. 1 has a first connecting arm 211 and a second connecting arm 212, each of which links the free end 201 and the fixed end 202. In the following description, when there are no limitations placed on the connecting arms of the arm portion 20, “connecting arm 210” will be used.

As illustrated in FIG. 1, a direction where the contact portion 11 extends from the linkage portion 12 of the tip portion 10 is designated as a Z direction. A plane perpendicular to the Z direction is designated as an XY plane. In FIG. 1, the Z direction is the up-down direction in the page space, an X direction is the left-right direction in the page space, and a Y direction is the depth direction in the page space. Hereinafter, a direction where an object to be inspected is located as viewed from the contact portion 11 of the tip portion 10 during inspection of the object to be inspected is also referred to as “tip direction”. That is, the Z direction, where the contact portion 11 extends from the linkage portion 12 in FIG. 1, is the tip direction.

An area of a connecting arm 210 that is nearest to the contact portion 11 from among multiple connecting arms 210, and is oriented in the tip direction, is called an installation area 200 of the arm portion 20. The guide portion 40 protruding in the tip direction is connected to the installation area 200 of the arm portion 20. In the probe 1, the arm portion 20 has the first connecting arm 211 and the second connecting arm 212, which are arranged along the tip direction apart from each other. The guide portion 40 is connected to the first connecting arm 211, which is closer to the contact portion 11 than the second connecting arm 212 is to the contact portion 11. When the arm portion 20 has multiple connecting arms 210, the guide portion 40 is connected to a connecting arm 210 nearest to the contact portion 11.

Before describing details of the probe 1 illustrated in FIG. 1, a probe (hereinafter referred to as “comparison probe 1M”) of a comparative example illustrated in FIG. 2 will be described. Similar to the probe 1 illustrated in FIG. 1, the comparative probe IM has the tip portion 10, the arm portion 20, and the support portion 30. A difference between the probe 1 illustrated in FIG. 1 and the comparative probe 1M is that the comparative probe 1M does not include the guide portion 40. When the comparative probe 1M without the guide portion 40 is used for inspection of an object to be inspected, for example, the following issue occurs.

In order to align an electrode pad of an object to be inspected with the tip portion 10 of the comparison probe 1M, a position of the tip portion 10 of the comparison probe 1M is measured, and the comparison probe 1M is mounted on a probe substrate with reference to the position of the tip portion 10. After the comparison probe 1M is mounted on the probe substrate, the position of the tip portion 10 is measured, and the amount of deviation of the tip portion 10 from the position of the electrode pad is investigated to guarantee the accuracy of the inspection. However, since only the position of the tip portion 10 of the comparison probe 1M is measured, distortion of the arm portion 20 cannot be detected.

When the comparison probe 1M in the distorted state is mounted on the probe substrate, it is not possible to bring the contact portion 11 of the tip portion 10 of the comparison probe 1M into precise contact with the center of the electrode pad of the object to be inspected. When the contact portion 11 is not in contact with the center of the electrode pad, an issue occurs, such as a decrease in contact strength between the comparison probe 1M and an object to be inspected. Consequently, the accuracy of inspection of the object to be inspected is lowered, and a measured value becomes inaccurate, or a good product is judged as a defective product.

In contrast, with the probe 1 illustrated in FIG. 1, the position of the contact portion 11 of the tip portion 10 and the position of the guide portion 40 can be measured separately. Thus, the amount of deviation on the XYZ coordinates as a whole of the probe 1 can be quantified on the basis of a relative positional relationship between the contact portion 11 and the guide portion 40. Therefore, the probe 1 enables distortion of the arm portion 20 to be detected.

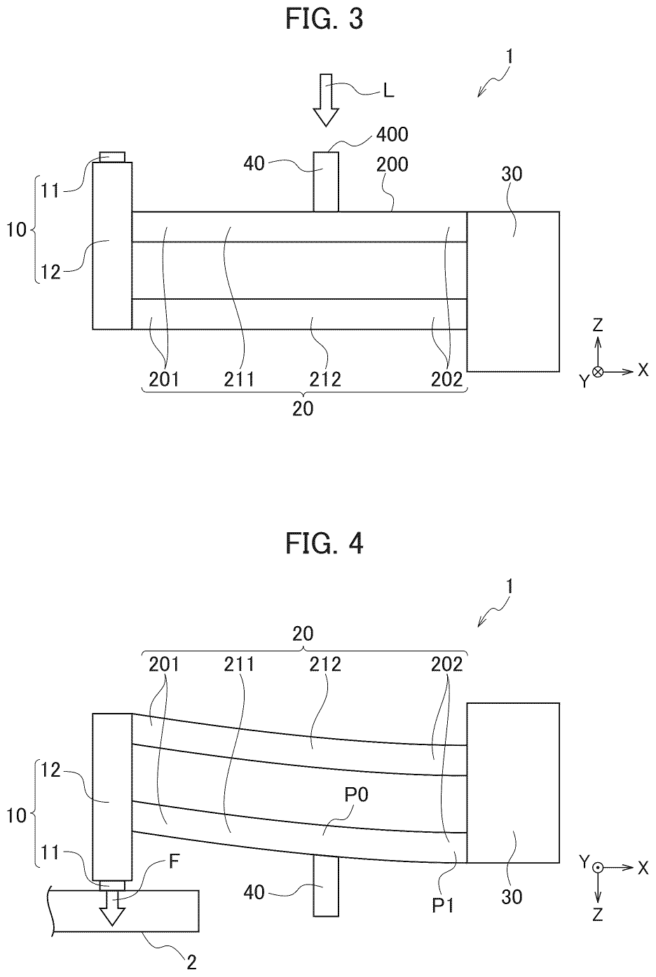

Note that a protruding surface 400 of the guide portion 40 oriented in the Z direction may be planar. When the protruding surface 400 of the guide portion 40 is planar, as illustrated in FIG. 3, by irradiating the guide portion 40 with light L from a plane normal to the protruding surface 400, the state of the probe 1 can be inspected using reflected light from the protruding surface 400. That is, the probe 1 with the light L not positively reflected from the protruding surface 400 is a defective probe having a posture defect, warping, or twisting. That is, with the probe 1, where the protruding surface 400 of the guide portion 40 is a plane, a defective probe can be detected using light reflected from the light L.

As described above, with respect to the probe 1 having the guide portion 40, it is possible to detect a defective probe using a relative positional relationship between the contact portion 11 and the guide portion 40, reflected light from the protruding surface 400, and the like. By detecting and discarding a defective probe before inspection of an object to be inspected, a decrease in inspection accuracy can be reduced. By excluding a defective probe before mounting it on a probe substrate, it is possible to reduce a replacement step for the probe 1, which has been mounted on the probe substrate.

The guide portion 40 can be arranged at any position of the arm portion 20. For example, the guide portion 40 may be arranged near the center of the arm portion 20. That is, the guide portion 40 may be arranged at an intermediate position between the free end 201 and the fixed end 202. The reason for arranging the guide portion 40 at the central position of the connecting arm 210 is as follows.

As illustrated in FIG. 4, when the contact portion 11 of the tip portion 10 comes into contact with an object to be inspected 2 during inspection thereof, the arm portion 20 curves in the Z direction. Elastic deformation of the arm portion 20 causes a force F that the contact portion 11 applies to the object to be inspected 2. That is, the arm portion 20 functions as a spring having elasticity. However, at the position where the guide portion 40 is arranged, elasticity of the arm portion 20 decreases, and thus a portion of the arm portion 20 functioning as a spring is shortened. Consequently, stress generated in the arm portion 20 increases. In particular, since a large stress is generated at an end position P1 close to the fixed end 202 of the arm portion 20 during inspection of the object to be inspected 2, it is preferable that the position where the guide portion 40 is arranged be far from the fixed end 202. In contrast, if the guide portion 40 is arranged at a position close to the free end 201, it is easy for the guide portion 40 to come into contact with the object to be inspected 2 when the arm portion 20 curve in the Z direction.

In contrast, stress generated at a center position P0 near the center of the arm portion 20 is smaller than that at the end position P1 near the fixed end 202. Thus, by arranging the guide portion 40 at the center position P0, influence due to the guide portion 40 on the stress can be reduced. In addition, the guide portion 40 arranged at a position distant from the free end 201 does not easily come in contact with the object to be inspected 2. Thus, by arranging the guide portion 40 at an intermediate position between the free end 201 and the fixed end 202, it is possible to reduce the influence of the guide portion 40 on the stress generated in the arm portion 20, and to prevent the contact between the object to be inspected 2 and the guide portion 40.

Furthermore, by arranging the guide portion 40 and the tip portion 10 at a certain distance from each other, it is easy to detect distortion or warpage of the arm portion 20 on the basis of a relationship between the position of the guide portion 40 and the position of the contact portion 11. Furthermore, since the support portion 30 is pressed against a probe substrate when the probe 1 is mounted on the probe substrate, it is preferable that the guide portion 40 be arranged at a certain distance from the support portion 30. Thus, from an operational point of view when mounting the probe 1 on the probe substrate, it is also preferable that the guide portion 40 be arranged at an intermediate position between the free end 201 and the fixed end 202.

The height of the guide portion 40 is, for example, about 10 um. Here, “height” of the guide portion 40 is a length in the Z direction from the surface of the installation area 200 to the protruding surface 400 of the guide portion 40. If the height of the guide portion 40 is too high, the guide portion 40 easily comes into contact with an object to be inspected. In contrast, if the height of the guide portion 40 is too low, it is difficult to measure the position of the guide portion 40. In addition, since the stress generated in the probe 1 during inspection increases as the size of the guide portion 40 increases, if the size of the guide portion 40 is too large, the contact portion 11 of the probe 1 is prevented from coming into contact with an object to be inspected with a predetermined force. Thus, the guide portion 40, which is set to a size that makes it easy to measure the position of the guide portion 40 and does not affect the inspection of an object to be inspected, is connected to the connecting arm 210.

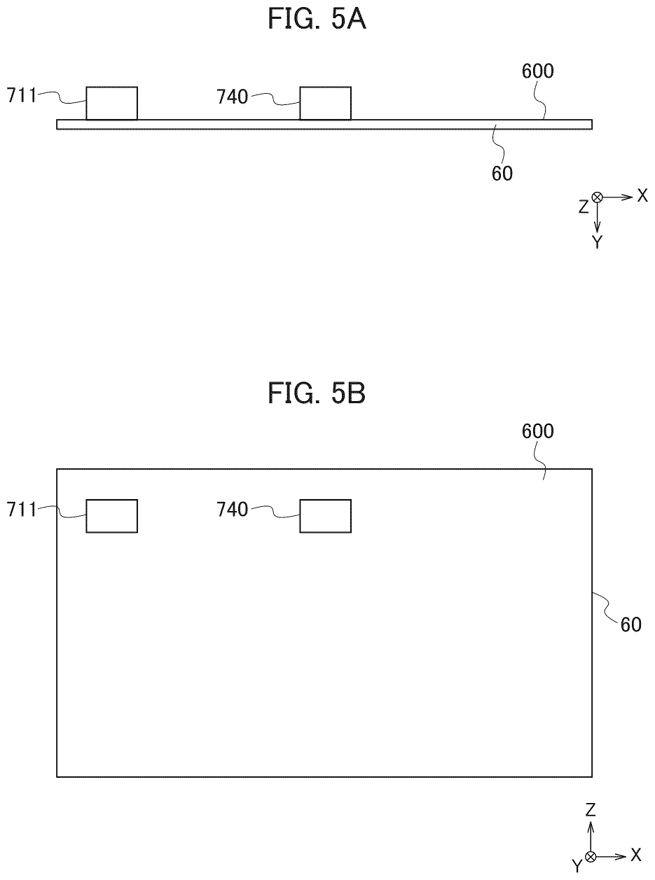

A method for manufacturing the probe 1 will be described below with reference to FIGS. 5A to 8B. Note that the method for manufacturing the probe 1 described below is an example, and the probe 1 can be manufactured by various other manufacturing methods including modifications of this example. FIGS. 5A, 6A, 7A, and 8A are plan views viewed from the tip direction (Z direction) where the guide portion 40 extends from the arm portion 20. FIGS. 5B, 6B, 7B, and 8B are side views seen from a direction (Y direction) perpendicular to each of the tip direction (Z direction) and an extension direction (X direction) of the arm portion 20.

First, as illustrated in FIGS. 5A and 5B, a sacrificial layer formed on a surface 600 of a substrate 60 is selectively removed to form a contact portion area 711 and a guide area 740 of the sacrificial layer at respective positions corresponding to positions of the contact portion 11 and the guide portion 40. For example, the contact portion area 711 and the guide area 740 are formed by performing patterning of a sacrificial layer using photolithography. The sacrificial layer is formed using copper plating, for example.

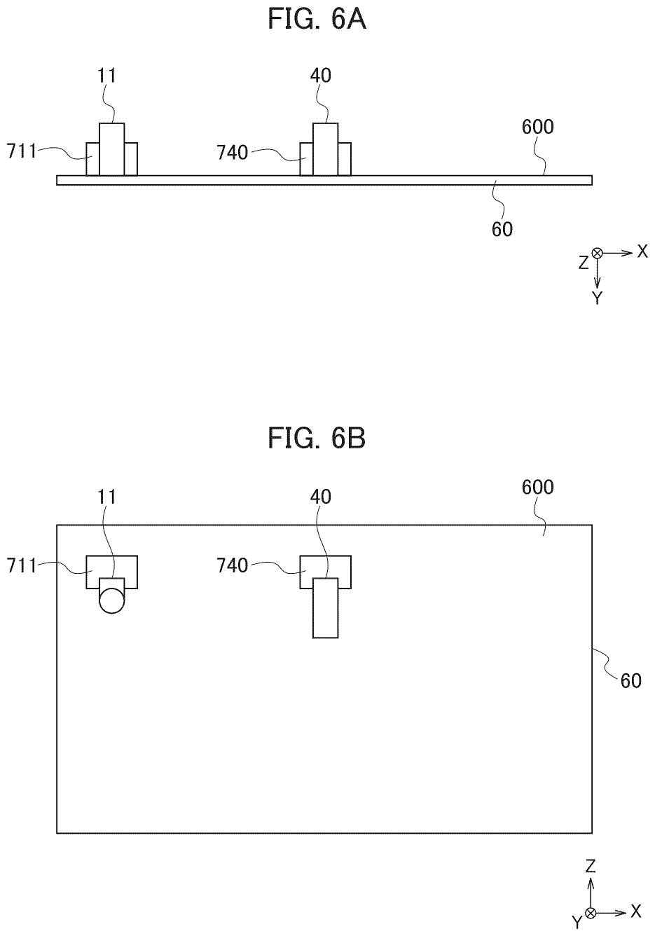

Next, as illustrated in FIGS. 6A and 6B, the contact portion 11 is formed on an upper surface and a side surface of the contact portion area 711, and the guide portion 40 is formed on an upper surface and a side surface of the guide area 740. In the guide portion 40, an area formed on the upper surface of the guide area 740 and an area formed on the side surface of the guide area 740 are continuous. In this way, the contact portion 11 and the guide portion 40 are formed simultaneously. For example, the contact portion 11 and the guide portion 40 may be formed by performing patterning of a metal film formed on the surface 600 of the substrate 60 using photolithography. The material of the contact portion 11 and the guide portion 40 is, for example, rhodium.

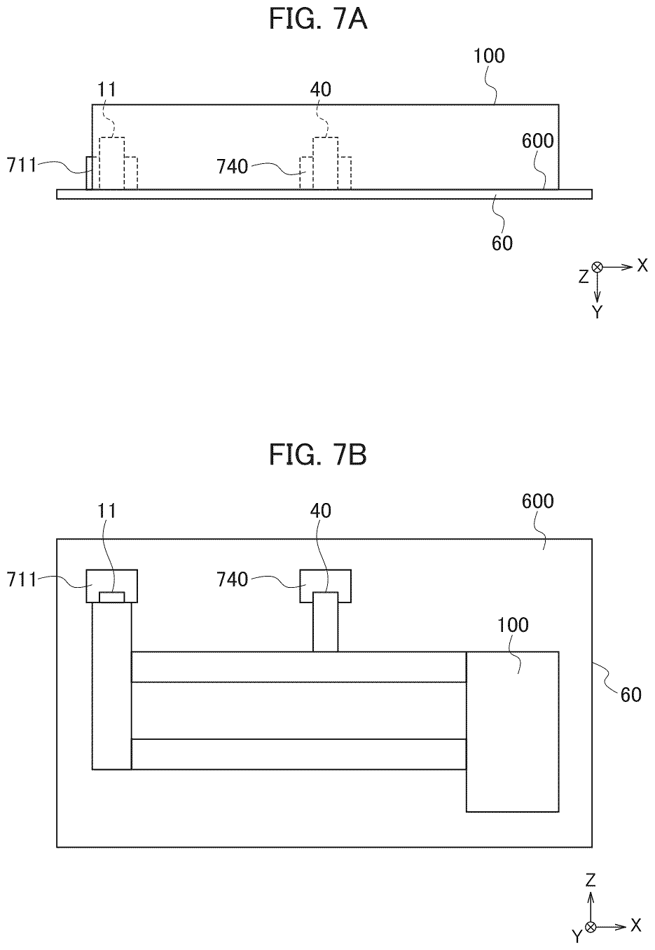

Then, as illustrated in FIGS. 7A and 7B, the remaining portion (hereinafter referred to as “body portion 100”) of the probe 1, excluding the contact portion 11 and the guide portion 40, is formed. That is, the contact portion 11 and the guide portion 40 are simultaneously connected to the body portion 100. A part formed on the side surface of the contact portion area 711 of the contact portion 11 is embedded in the body portion 100. At least part of the area formed on the side surface of the guide area 740 of the guide portion 40 is embedded in the body portion 100. The material of the body part 100 is, for example, nickel.

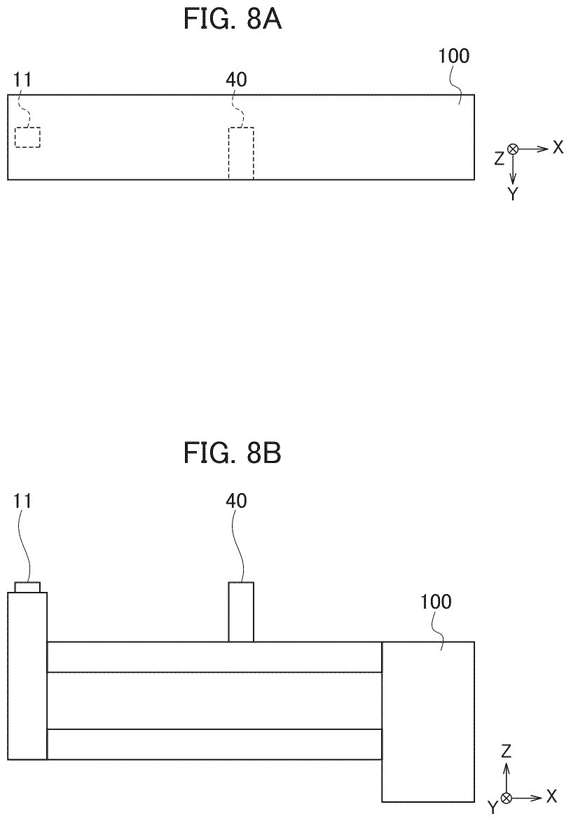

Then, as illustrated in FIGS. 8A and 8B, after removing the sacrificial layer, the probe 1 is taken off from the substrate 60. Thus, the probe 1 is completed.

According to the manufacturing method described above, the contact portion 11 of the tip portion 10 and the guide portion 40 are formed simultaneously in the same process. By forming the guide portion 40 at the same time as the contact portion 11, accuracy of a relative positional relationship between the tip portion 10 and the guide portion 40 can be increased. Since there is no positional deviation of the contact portion 11 and the guide portion 40 in the manufacturing process of the probe 1, it is also possible to accurately detect the position of the probe 1 without observing the tip portion 10, for example.

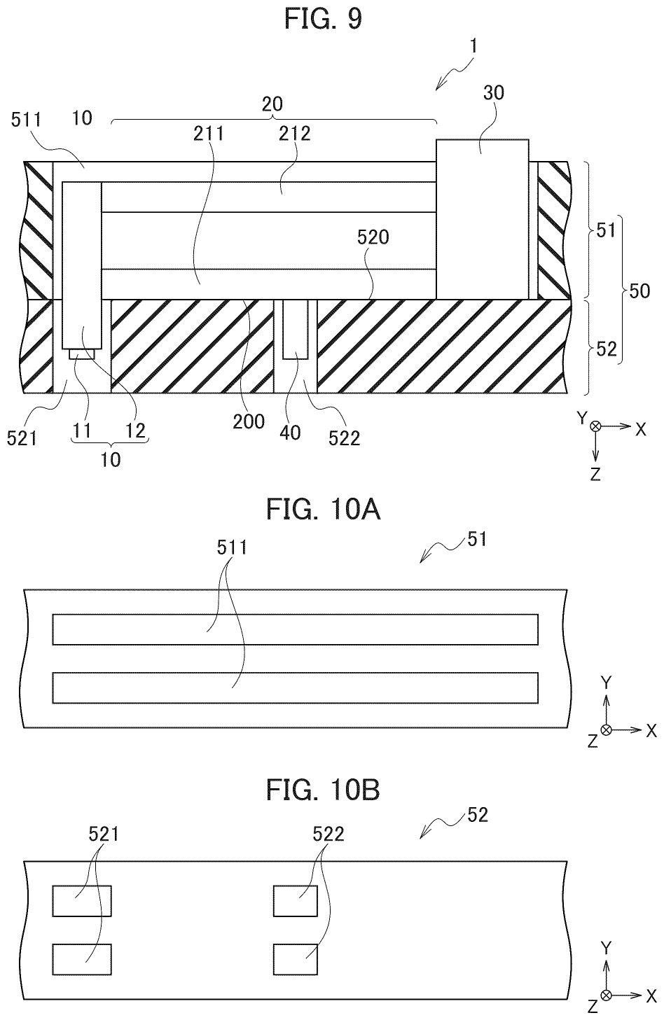

The probe 1 may be held, for example, by a probe holding device 50 illustrated in FIG. 9. The probe holding device 50 has a first guide plate 51 having a slit 511 that the probe 1 penetrates in the Z direction, and a second guide plate 52 arranged to overlap with the first guide plate 51 when viewed from the Z direction. A first storage space 521 where a part including at least the contact portion 11 of the tip portion 10 is housed, and a second storage space 522 where the guide portion 40 is housed, are formed on a main surface 520 of the second guide plate 52 being opposed to the first guide plate 51. The slit 511 penetrates the first guide plate 51 in the thickness direction. The first storage space 521 and the second storage space 522 penetrate the second guide plate 52 in the thickness direction. With the first guide plate 51 and the second guide plate 52 overlapping, the first storage space 521 and the second storage space 522 communicate with the slit 511.

The probe holding device 50 holds the probe 1 with the installation area 200 of the arm portion 20 opposed to the main surface 520 of the second guide plate 52. For example, a portion of the installation area 200 excluding the area where the guide portion 40 is arranged comes into contact with the remaining area of the main surface 520 of the second guide plate 52, excluding the area where the first storage space 521 and the second storage space 522 are formed. Part of the support portion 30 of the probe 1 may be exposed outside the first guide plate 51.

The first connecting arm 211 having the installation area 200 has a linear shape. In other words, the installation area 200 extends linearly between the free end 201 and the fixed end 202. Thus, the probe holding device 50 holds the probe 1 in a stable posture of the probe 1 where the tip portion 10 is housed in the first storage space 521, the guide portion 40 is housed in the second storage space 522, and the main surface 520 of the second guide plate 52 is in contact with the installation area 200. For example, with the probe I held in the probe holding device 50, the probe I can be transported with its posture stabilized.

Further, by forming the guide portion 40 at the same time as the contact portion 11, the accuracy of the relative positional relationship between the tip portion 10 and the guide portion 40 can be increased. Thus, when the probe 1 is stored in the probe holding device 50, it is easy to store the guide portion 40 in the second storage space 522 of the second guide plate 52 at the same time as storing the tip portion 10 in the first storage space 521.

The probe holding device 50 for holding multiple probes 1 may have one first guide plate 51 and one second guide plate 52. That is, the first guide plate 51 may have multiple slits 511, and the second guide plate 52 may have multiple first storage spaces 521 and second storage spaces 522. FIG. 10A and FIG. 10B illustrate plan views of the first guide plate 51 and the second guide plate 52 viewed from the tip direction. FIG. 10A illustrates the first guide plate 51, where slits 511 corresponding to two probes 1 are formed. FIG. 10B illustrates the second guide plate 52, where first storage spaces 521 and second storage spaces 522 corresponding to two probes 1 are formed.

A flexible film, such as a resin film, is preferably used as the material of the first guide plate 51. By using a material having low mechanical hardness for the first guide plate 51 in the probe holding device 50, when the probe 1 is inserted into the slit 511 of the first guide plate 51, it is possible to prevent the probe 1 from coming into contact with and breaking the first guide plate 51. Alternatively, reinforced plastic or ceramic may be used as the material of the first guide plate 51.

For example, ceramic may be used as the material of the second guide plate 52. The probe 1 can be stably held by the probe holding device 50 by using a material that has enough mechanical strength to prevent the second guide plate 52 from bending. For example, a material harder than that of the first guide plate 51 may be used for the material of the second guide plate 52.

As described above, the probe 1 according to the embodiment includes the guide portion 40, which is connected to the installation area 200 of the connecting arm 210 oriented in the tip direction, where an object to be inspected is located as viewed from the contact portion 11, and protrudes in the tip direction from the installation area 200. Distortion of the probe 1 can be detected on the basis of the position of the contact portion 11 and the position of the guide portion 40. In addition, with the probe holding device 50, the probe 1, which is easy to detect distortion, can be stably held and transported.

### Modified Examples

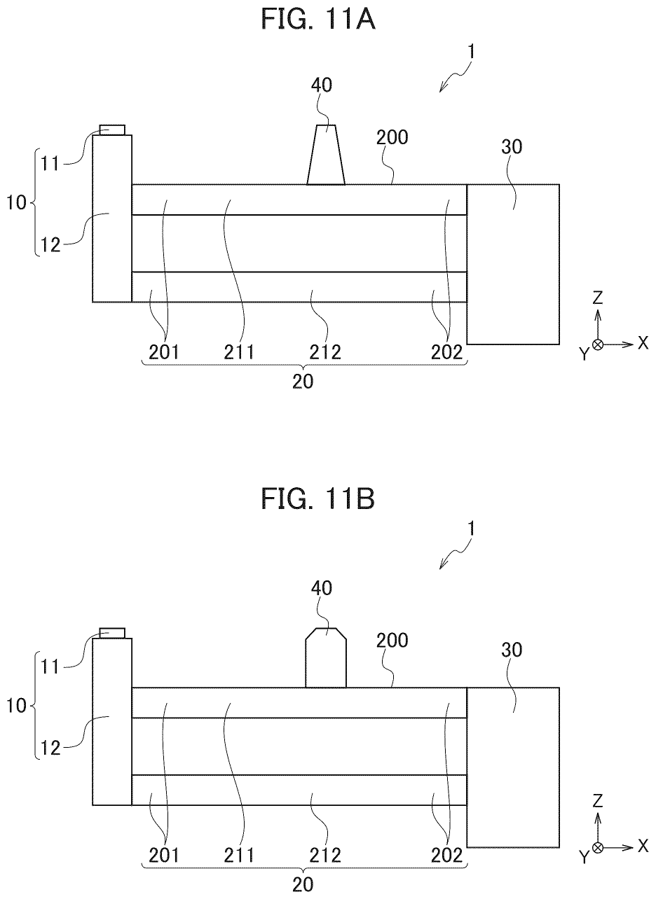

In the above description, the guide portion 40 has a rectangular shape as viewed from the Y direction (hereinafter, also referred to as “width direction”) of the connecting arm 210, perpendicular to the Z direction and the X direction, where the connecting arm 210 extends. However, the shape of the guide portion 40 may be any shape as long as the position of the guide portion 40 can be measured. For example, as illustrated in FIG. 11A, the shape of the guide portion 40 viewed from the width direction of the arm portion 20 may be trapezoidal. Alternatively, as illustrated in FIG. 11B, the shape of the guide portion 40 viewed from the width direction of the arm portion 20 may be a shape where a trapezoidal portion is placed on a rectangular portion. The guide portion 40 is easily housed in the second storage space 522 of the second guide plate 52 by making part of the guide portion 40 protruding smaller than part thereof connected to the installation area 200.

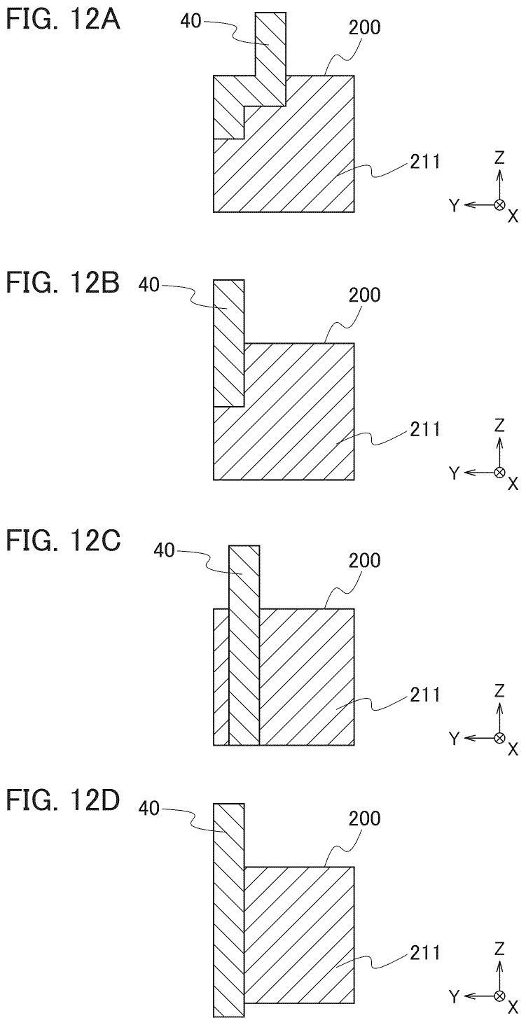

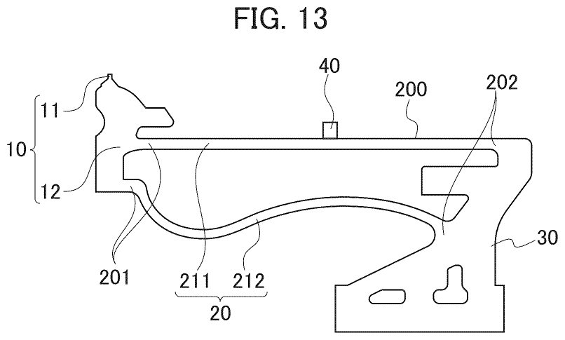

In addition, a position where the guide portion 40 is connected to the connecting arm 210 can be set as desired in the width direction of the connecting arm 210. FIGS. 12A to 12D are cross-sectional views of the guide portion 40 and the first connecting arm 211 along the width direction of the first connecting arm 211 to which the guide portion 40 is connected. FIG. 12A is an example of the guide portion 40 arranged near the center of the first connecting arm 211 in the width direction. FIG. 12B is an example of the guide portion 40 arranged near an end portion of the first connecting arm 211 in the width direction. FIG. 12C is an example of the guide portion 40 whose connection portion with the first connecting arm 211 penetrates the first connecting arm 211. FIG. 12D is an example of the guide portion 40 whose portion penetrating the first connecting arm 211 extends beyond the area opposite to the installation area 200 of the first connecting arm 211.

### Other Embodiments

Although the present invention has been described by means of the embodiments as described above, the statements and drawings that form part of the disclosure should not be understood as limiting the invention. Various alternative embodiments, examples, and operational techniques will be apparent to those skilled in the art from the disclosure.

For example, although the case where the connecting arm 210 has a straight shape has been described above, the second connecting arm 212 may have a curved shape as illustrated in FIG. 13. By setting the elastic modulus of the arm portion 20 according to the degree of curvature of the second connecting arm 212, or by material selection, the force applied to an object to be inspected at the contact portion 11 can be adjusted. Although the case where the number of connecting arms 210 of the arm portion 20 is two has been exemplarily described, the number of connecting arms 210 included in the arm portion 20 may be 3 or more.

As described above, the present invention of course includes various embodiments not described herein.

### Reference Signs List

1 Probe
10 Tip portion
11 Contact portion
12 Linkage portion
20 Arm portion
30 Support portion
40 Guide portion
50 Probe holding device
51 First guide plate
52 Second guide plate
200 Installation area
201 Free end
202 Fixed end
211 First connecting arm
212 Second connecting arm
400 Protruding surface
511 Slit
521 First storage space
522 Second storage space

1. A probe used for inspection of an object to be inspected, comprising:
a tip portion that includes a contact portion which comes into contact with the object to be inspected;
an arm portion that has a cantilever structure including a connecting arm which links a free end and a fixed end thereof, the free end being connected to the tip portion;
a support portion that is connected to the fixed end; and
a guide portion that is connected to an installation area of the arm portion, oriented in a tip direction where the object to be inspected is located as viewed from the contact portion, and that protrudes in the tip direction from the installation area.

2. The probe according to claim 1, wherein the guide portion is arranged at an intermediate position between the free end and the fixed end.

3. The probe according to claim 1, wherein a protruding surface of the guide portion oriented in the tip direction is planar.

4. The probe according to claim 1, wherein the installation area extends linearly between the free end and the fixed end.

5. The probe according to claim 1, wherein
the arm portion includes a first connecting arm and a second connecting arm arranged along the tip direction apart from each other, and
the guide portion is connected to the first connecting arm, which is closer to the contact portion than the second connecting arm is to the contact portion.

6. A probe holding device for holding the probe according to claim 1, comprising:
a first guide plate that has a slit that the probe penetrates in the tip direction; and
a second guide plate that is arranged to overlap the first guide plate when viewed from the tip direction, and includes: a first storage space where a part including at least the contact portion of the tip portion is housed; and a second storage space where the guide portion is housed, the first storage space and the second storage space being formed on a main surface of the second guide plate opposed to the first guide plate, wherein
the probe is held in a state where a remaining area of the main surface of the second guide plate, excluding an area where the first storage space is formed and an area where the second storage space is formed, is in contact with the installation area of the arm portion.

7. A method for manufacturing the probe according to claim 1, comprising:
forming the contact portion of the tip portion and the guide portion simultaneously.
